(19) United States
(12) Patent Application Publication
(10) Pub. No.: US 2026/0038559 A1
(43) Pub. Date: Feb. 5, 2026

(54) APPARATUSES SYSTEMS AND METHODS FOR SELF-REFRESH RATE CONTROL

(71) Applicant: Micron Technology, Inc., Boise, ID (US)

(72) Inventors: Wonjun Choi, Boise, ID (US); Hyun Yoo Lee, Boise, ID (US); Joo-Sang Lee, Frisco, TX (US)

(73) Assignee: Micron Technology, Inc., Boise, ID (US)

(21) Appl. No.: 18/790,364

(22) Filed: Jul. 31, 2024

(51) Int. Cl. G11C 11/406; G11C 11/4099

(52) U.S. Cl. CPC G11C 11/40615; G11C 11/40622; G11C 11/4099

(57) ABSTRACT

A memory device performs self-refresh operations during a self-refresh mode. The self-refresh operations are performed at a rate. The memory includes a self-refresh rate adjustment circuit which reduces the rate of the self-refresh operation if certain conditions are met. In an example, the self-refresh rate may be reduced if a temperature rises above a threshold. In an example, the self-refresh rate may be reduced if a system voltage falls below a reference voltage.

### BACKGROUND

This disclosure relates generally to semiconductor devices, and more specifically to semiconductor memory devices. In particular, the disclosure relates to volatile memory, such as dynamic random access memory (DRAM). Information is stored in the memory on memory cells as a physical signal such as a charge on a capacitive element. During an access operation, an access command may be received along with address information which specifies which memory cells should be accessed.

Information may decay over time in the memory cells. For example, the memory cells may discharge over time. In order to preserve the integrity of the stored information, the memory cells may be refreshed, for example to restore an initial charge level associated with the stored information. The memory receives a refresh command which instructs it to perform one or more refresh operations. The memory may also enter a self-refresh mode, for example while the memory is in an idle state, where the memory performs refresh operations on itself. It may be useful to adjust the self-refresh rate to prevent certain conditions of the memory which may damage the device.

### BRIEF DESCRIPTION OF THE DRAWINGS

FIG. 1 is a block diagram of a semiconductor device according to some embodiments of the disclosure.

FIG. 2 is a block diagram of refresh logic circuits according to some embodiments of the present disclosure.

FIG. 3 is a block diagram of self-refresh logic according to some embodiments of the present disclosure.

FIG. 4 is timing diagram of adjusting self-refresh operations based on temperature according to some embodiments of the present disclosure.

FIG. 5 is a flow chart of a method of adjusting a self-refresh rate based on temperature according to some embodiments of the present disclosure.

FIG. 6 is a timing diagram of adjusting self-refresh operations based on voltage according to some embodiments of the present disclosure.

FIG. 7 is a flow chart of a method of adjusting a self-refresh rate based on voltage according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells. The memory cells are at the intersection of bit lines and word lines. The bit lines and word lines may be considered as columns and rows respectively in a logical organization of the array. The memory array is also divided into multiple banks. Accordingly, a row address may specify one or more word lines, a column address may specify one or more bit lines, and a bank address may specify one or more banks.

The memory cells may store information in a manner which decays over time. In an example implementation, the memory cell may include a capacitive element, and the charge on the capacitive element represents if the memory cell stores a logical high or a logical low. The charge may leak over time. In order to preserve information in the array, refresh operations may be performed. For example, the refresh operation may restore the charge to an initial value representing the state of the stored bit.

The memory may perform refresh operations responsive to refresh commands. For example, the memory may receive all bank refresh commands, per-bank refresh commands, or same bank refresh commands. In certain modes, the memory may also perform self-refresh operations. The memory includes a self-refresh oscillator circuit which periodically generates a self-refresh signal. Responsive to the self-refresh signal, the memory performs a refresh operation. The rate at which the self-refresh signal is generated may be based, in part, on conditions of the memory. Certain conditions may cause a rate of the self-refresh operations to increase to a point which can cause problems for the memory. For example, as the temperature of the memory increases, the memory may increase the rate at which self-refresh operations occur. However, frequent refresh operations may in turn also increase the temperature, leading to an undesirable positive feedback loop which may cause damage to the memory. A high rate of self-refresh operations may, instead or in addition, also cause a high rate of power consumption on the memory. The high rate of power consumption may outpace the amount of power the power supply can provide, which may destabilize the level of one or more system voltages. Accordingly, it may be useful to use conditions of the memory to adjust the rate of self-refresh operations.

The present disclosure is drawn to apparatuses, systems, and methods for self-refresh rate control. An example memory device adjusts the self-refresh rate based on one or more properties of the memory. For example, the memory adjust the self-refresh rate based on a measured temperature of the memory, a voltage of the memory, or both. A self-refresh rate adjustment circuit compares property(ies) to a threshold, and adjusts the rate at which the self-refresh signal is generated based on the comparison. In some embodiments, the self-refresh rate adjustment circuit may reduce the rate of self-refresh operations below a level required to maintain the integrity of data stored on the device in order to protect the memory from damage.

In some example embodiments, the memory device includes a temperature sensor which measures a temperature of the memory. The self-refresh rate adjustment circuit compares the temperature to a first threshold and a second threshold which is higher than the first threshold. If the temperature is above the first threshold but below the second threshold, the self-refresh rate adjustment circuit may increase a rate of self-refresh operations. If the temperature is above the second threshold, the self-refresh rate adjustment circuit may decrease the rate of self-refresh operations.

In some example embodiments, the memory device adjusts the self-refresh rate based on a voltage. For example, the voltage sensor may measure a system voltage VDD. The self-refresh rate adjustment circuit compares the system voltage to a reference voltage. If the system voltage falls below the reference voltage, then the self-refresh adjustment circuit decreases the rate of self-refresh operations. The system voltage may be a voltage which is used as part of refresh operations, while the reference voltage is not used in refresh operations. In this way a voltage which is affected by the self-refresh operations may be compared to a reference.

In some example embodiments, a memory device may both adjust the self-refresh rate based on temperature and voltage.

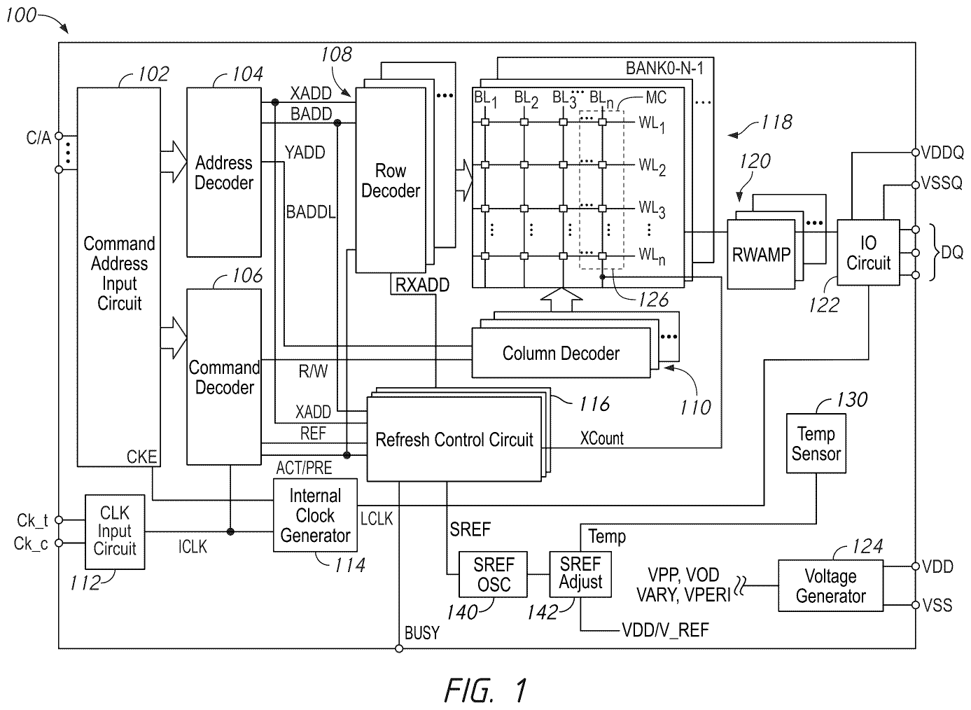

FIG. 1 is a block diagram of a semiconductor device according to some embodiments of the disclosure. The semiconductor device 100 may be a semiconductor memory device, such as a DRAM device integrated on a single semiconductor chip. In some embodiments, the semiconductor device 100 may represent one of a number of memory devices packaged together, such as on a module. In some embodiments, the semiconductor device 100 may represent a stand-alone memory device.

The semiconductor device 100 includes a memory array 118. The memory array 118 is organized into a plurality of memory banks. In the embodiment of FIG. 1, the memory array 118 is shown as including N memory banks labeled BANK0 to BANKN−1. For example, a memory array 118 may include 4, 8, 16, 32 or any other number of memory banks. More or fewer banks may be included in the memory array 118 of other embodiments.

Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). Read data from the bit line BL is amplified by the sense amplifier SAMP, and transferred to read/write amplifier (RWAMP) circuit 120 over local data lines (LIO), transfer gate (TG), and global data lines (GIO). Conversely, write data outputted from the RWAMP circuit 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A or CA) terminals coupled to a command and address bus to receive commands and addresses, clock terminals to receive clocks CK and/CK, data terminals DQ coupled to a data bus to provide data, and power supply terminals to receive power supply potentials VDD, VSS, VDDQ, and VSSQ. The external terminals may also generally be referred to as ‘pins’ such as C/A pins. In some embodiments, the external terminals may couple directly to a host or controller of the memory device 100. In some embodiments, the external terminals may couple to various buses/connectors of a module or other package. In some embodiments, each terminal may generally receive a first voltage which represents a logical high or a second voltage which represents a logical low. Other schemes, such as multi-level signaling (e.g., PAM4) may be used in other example embodiments.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses. The memory addresses supplied to the C/A terminals are transferred, via a command/address input circuit 102, to an address decoder 104. The address decoder 104 decodes the address into a bank address, row address, and column address. The bank address BADD selects the row decoder 108 and column decoder 110 and thus selects the bank. The address decoder 104 supplies a decoded row address XADD to the row decoder 108 selected by BADD and supplies a decoded column address YADD to the column decoder 110 selected by BADD. The decoded row address XADD may be used to determine which row is opened or activated, coupling the memory cells along the activated word line to the intersecting bit lines. The column decoder 110 provides a column select signal CS based on the column address YADD. The CS signal selects which bit lines are coupled to local input/output lines, allowing those bit lines to be accessed.

The C/A terminals may be supplied with commands. Examples of commands include timing commands for controlling the timing of various operations, access commands for accessing the memory, such as row activation commands, read commands for performing read operations, write commands for performing write operations, and pre-charge commands, refresh commands such as all-bank refresh, same bank refresh, and per-bank refresh, as well as other commands and operations. The access commands may be associated with one or more row address XADD, column address YADD, and bank address BADD to indicate the memory cell(s) to be accessed. In some embodiments, the command and address may be transmitted together as a command packet along the C/A terminals. The input circuit 102 separates the command portion of the packet from the address portion and provides the command portion to the command decoder 106 and the address portion to the address decoder 104.

The commands may be provided as internal command signals to a command decoder 106 via the command/address input circuit 102. The command decoder 106 includes circuits to decode the internal command signals to generate various internal signals and commands for performing operations. For example, the command decoder 106 may provide signals to indicate if data is to be read, written, etc. Responsive to an activation command received at the C/A terminals, as part of an access operation the command decoder 106 provides an internal row activation command or internal row activation signal ACTN or ACTL. Responsive to a pre-charge command the command decoder 106 provides an internal pre-charge command or internal pre-charge signal Pre. The row decoder 108 activates a word line responsive to the internal activation signal ACT and deactivates (or pre-charges) the word line responsive to the internal pre-charge signal Pre.

In an example write operation, the device 100 writes data received at the DQ terminals to the memory cells specified by a received bank, row and column address. As part of the write operation, the command decoder 106 receives a write command and activation command and provides internal signals such as W and ACT/Pre. The write data is received by the IO circuit 122 and provided to the RWAMP circuit 120. The row decoder 108 selected by BADD activates the row selected by XADD responsive to the internal activation signal ACT. The column decoder 110 selected by BADD couples the bit lines selected by YADD to the LIO and GIO lines to the RWAMP circuit 120. The sense amplifiers drive the voltages on the coupled bit lines to write the write data to the memory cells at the intersection with the active word line.

In an example read operation, the device 100 reads data from the memory cells specified by a received bank, row, and column address and provides that read data to the DQ terminals. As part of the read operation, the command decoder 106 receives a read command and an activation command and provides internal signals such as a read signal R, and ACT/Pre. The row decoder 108 selected by BADD activates the row selected by XADD responsive to the internal row activation signal ACT. The column decoder 110 selected by BADD couples the bit lines selected by YADD to the LIO and GIO lines to the RWAMP circuit 120. The RWAMP circuit 120 provides the read data to the IO circuit 122 and the IO circuit 122 provides the read data to the DQ terminals.

The device 100 includes refresh control circuits 116 each associated with a bank of the memory array 118. Each refresh control circuit 116 performs refresh operations on the associated bank by providing a refresh address RXADD, along with one or more refresh signals. The refresh control circuits 116 may perform one or more refresh operations responsive to a refresh command. For example, the memory may receive an all-bank refresh command REFab along the C/A terminals, and the command decoder 106 provides a refresh signal REF to all of the refresh control circuits 116. Responsive to the refresh signal REF, the refresh control circuits 116 perform refresh operations. The memory may also receive commands such as a per-bank refresh command REFpb or same-bank refresh command REFsb, which specify which bank or banks the command decoder 106 should provide the refresh signal to.

Refresh operations may include one or more normal refresh operations, one or more targeted refresh operations, or combinations thereof. In a normal refresh operation, the refresh address is generated based on sequence logic. For example a refresh address counter may increment to generate a new refresh address, such as RXADD (i)=RXADD (i−1)+1. In a targeted refresh operation, an identified aggressor address is used to generate refresh addresses. The refresh addresses may be adjacent to the aggressor, for example RXADD=Aggressor+/−1.

The refresh control circuit 116 also tracks accesses to word lines of the respective banks to determine if a targeted refresh operation should be performed. Memory cells along each word line are set aside as counter memory cells 126. The counter memory cells store a per-row access count (PRAC) value associated with a number of times that the respective word line has been accessed. When a word line is accessed or refreshed, its PRAC value is read out to the refresh control circuit 116 which updates (e.g., increments) the count value and determines if the count has crossed a threshold as part of an access count update (ACU) operation. If the PRAC value has crossed a mitigation threshold, then the address is added to an aggressor queue for a later targeted refresh operation. When a targeted refresh operation is performed, one or more victim word lines of the aggressor word line are refreshed.

The memory device 100 may enter a self-refresh mode, where the memory performs refresh operations on itself without the need for external commands. In some embodiments, the memory device 100 may receive a self-refresh entry command and begin performing self-refresh operations until receiving a self-refresh exit command. In some embodiments, the memory 100 may automatically begin performing self-refresh operations in certain modes or states, such as in an idle state. The memory device includes a self-refresh oscillator circuit 140, which provides a self-refresh signal SREF when the memory is in the self-refresh mode. The refresh control circuits 116 receive SREF and perform one or more refresh operations responsive to SREF. In some embodiments, only normal refresh operations are performed during the self-refresh mode. The memory may activate a self-refresh enable signal in the self-refresh mode, and deactivate the self-refresh enable signal when not in the self-refresh mode.

The self-refresh oscillator circuit may provide SREF with periodic timing when in the self-refresh mode. The frequency of that periodic timing is determined by a self-refresh rate adjustment circuit 142. As described in more detail herein, the self-refresh rate adjustment circuit 142 circuit may change the rate of the self-refresh operations based on one or more conditions of the memory. For example, the self-refresh rate adjustment circuit 142 may use a temperature measured by a temperature sensor 130, a voltage, or both to determine the self-refresh rate.

The power supply terminals are supplied with power supply potentials VDD and VSS. The power supply potentials VDD and VSS are supplied to an internal voltage generator circuit 224. The internal voltage generator circuit 224 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 222. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks. The voltages VDD and VSS (or voltages derived therefrom) may generally be used by circuits of the memory such as the array 118, row decoder 108, refresh control circuit 116 and others. The voltages VDDQ and VSSQ may generally be used by the input/output circuit 122 and not by other components of the memory device 100.

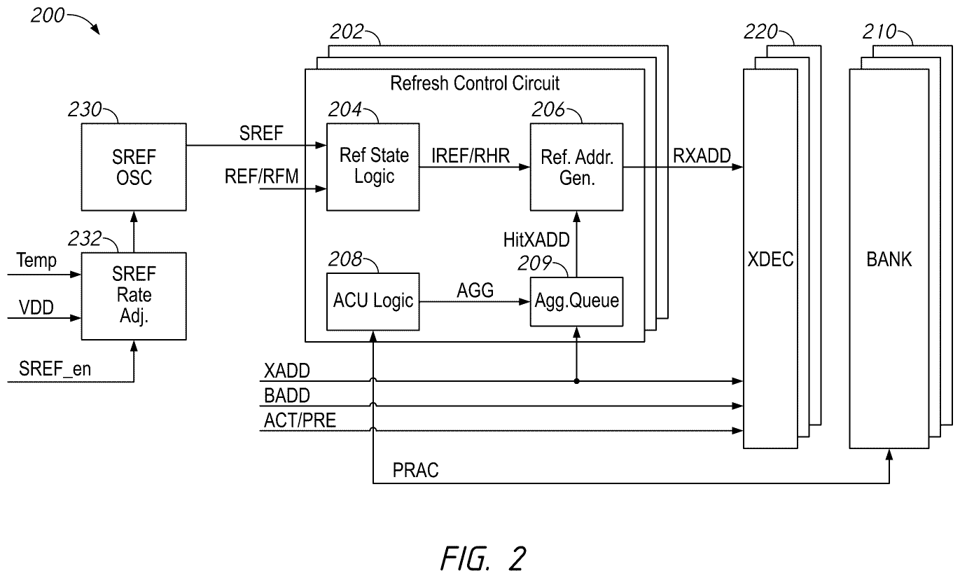

FIG. 2 is a block diagram of refresh logic circuits according to some embodiments of the present disclosure. The refresh logic circuits 200 may, in some embodiments, represent a portion of the memory device 100 of FIG. 1. The refresh logic circuits 200 show refresh control circuits 202 (e.g., 116 of FIG. 1), row decoders 220 (e.g., 108 of FIG. 1) and memory array 210 (e.g., 118 of FIG. 1) as well as a self-refresh oscillator circuit 230 and a self-refresh rate adjustment circuit 232. The memory array 210 is divided into a number of banks 212. There is a refresh control circuit 202 and row decoder 220 associated with each bank. Since the refresh control circuits 202 and row decoders 220 may be generally similar to each other, only one will be described in detail as an example. The self-refresh oscillator circuit 230 and self-refresh rate adjustment circuit 232 may be shared between the banks 210.

The refresh control circuit 202 includes a refresh state logic circuit 204, a refresh address generator circuit 206, an ACU logic circuit 208, and an aggressor queue 209. The refresh state logic circuit 204 determines if one or more refresh operations should be performed, what type(s) should be performed, and how many operations should be performed. The refresh address generator 206 generates a refresh address RXADD for each refresh operation. The ACU logic 208 manages ACU operations to determine which addresses are aggressor addresses to be stored in the aggressor queue 209.

During an access operation, the bank logic 200 receives a bank address BADD and row address XADD. Responsive to an activation signal ACT, the row decoder 220 specified by the bank address BADD accesses the specified bank 214 and activates the word line specified by XADD. Responsive to the signal Pre, the specified row decoder 220 pre-charges the word line. While the word line is active, its PRAC value is read out to the ACU logic circuit 208, which updates the PRAC value and writes it back. For example, the ACU logic circuit 208 may perform a read/modify/write cycle on the counter memory cells (e.g., 126 of FIG. 1).

The ACU logic circuit 208 compares the updated PRAC value to a mitigation threshold. For example, the ACU logic circuit 208 may increment the PRAC value and determine if it is equal to or greater than the mitigation threshold. If the PRAC value has crossed the mitigation threshold, then the ACU logic circuit 208 provides an aggressor signal AGG. Responsive to the aggressor signal AGG, the aggressor queue 209 stores the current address XADD as an aggressor address.

The refresh control circuit performs refresh operations responsive to refresh signals such as a self-refresh signal SREF, a refresh signal REF, or a refresh management signal RFM. The refresh signal REF may be provided responsive to a refresh command such as a all-bank, per-bank, or same-bank refresh command. The refresh management signal RFM may be provided responsive to refresh management command. The self-refresh signal is provided by a self-refresh oscillator circuit 230 (e.g., 140 of FIG. 1) during a self-refresh mode. Responsive to one of the refresh signals REF, RFM, or SREF, the refresh control circuit 202 performs one or more refresh operation. A refresh state logic circuit 204 determines how many refresh operation and what type(s) of refresh operation to perform responsive to REF, RFM, or SREF.

The refresh state logic circuit 204 performs refresh operations by providing internal refresh signals IREF and RHR. The internal refresh signal IREF indicates a normal refresh operation, while the targeted refresh signal RHR indicates a targeted refresh operation. The refresh state logic circuit 204 may issue multiple activations of one or both of IREF and RHR when given the opportunity to perform refresh operations. In some embodiments, responsive to REF, the refresh state logic 204 may provide a mix of IREF and RHR to perform a mix of normal and targeted refresh operations. For example, responsive to REF, the refresh state logic circuit 204 may perform two normal refresh operations and two targeted refresh operations. Other numbers and ratios of normal and targeted refresh operations may be performed in other embodiments. In some embodiments, responsive to RFM, only targeted refresh operations may be performed. In some embodiments, responsive to SREF, only normal refresh operations may be performed.

The refresh address generator circuit 206 provides a refresh address RXADD responsive to IREF or RHR. Responsive to IREF, the refresh address generator circuit 206 generates the refresh address based on sequence logic. For example, a refresh address counter may be incremented and used to generate the refresh address. In some embodiments, multiple word lines may be refreshed at the same time responsive to IREF as part of a normal refresh operation. For example, as part of a normal refresh operation, the refresh address generator 206 generates a refresh address RXADD where some of the bits are masked. The row decoder 220 may refresh each of the word lines which share the non-masked bits of the refresh address in common. For example if two bits are masked, then four word lines may be refreshed at once. The normal refresh operation may be performed responsive to SREF as part of a self-refresh operation or responsive to REF responsive to a refresh command.

Responsive to RHR, the refresh address generator circuit 206 uses an aggressor address HitXADD provided by the aggressor queue 209 to generate the refresh address RXADD. For example, the refresh address generator circuit 206 may refresh the word lines on either side of the aggressor, and then reset the PRAC value along the aggressor. The targeted refresh operation may be performed responsive to REF as part of a refresh command or responsive to RFM as part of a refresh management command.

When the memory is in a self-refresh mode, the self-refresh oscillator circuit 230 periodically provides the self-refresh signal SREF. Responsive to each activation of SREF, the refresh control circuit performs one or more refresh operations, such as normal refresh operations. In some embodiments, the signal SREF may be a pulsed signal, and one or more refresh operations are performed responsive to each pulse. In the self-refresh mode, a self-refresh enable signal SREF_en is active, for example at a logical high level. For example, the memory may receive a self-refresh entry command and activate the signal SREF_en until a self-refresh exit command is received. In some embodiments, the memory may automatically activate SREF_en in certain states of the memory.

During the self-refresh mode, the memory may not generally be expected to receive other commands, and so other signals such as REF, RFM, ACT and PRE may be inactive. The rate at which the self-refresh signal SREF is provided by the oscillator circuit 230 is determined by a self-refresh rate adjustment circuit 232 (e.g., 142 of FIG. 1). The self-refresh rate adjustment circuit 232 may set a rate of the self-refresh oscillator circuit 230 based on one or more properties of the memory, such as a temperature (e.g., as measured by the temperature sensor 130 of FIG. 1), a system voltage such as VDD, or combinations thereof.

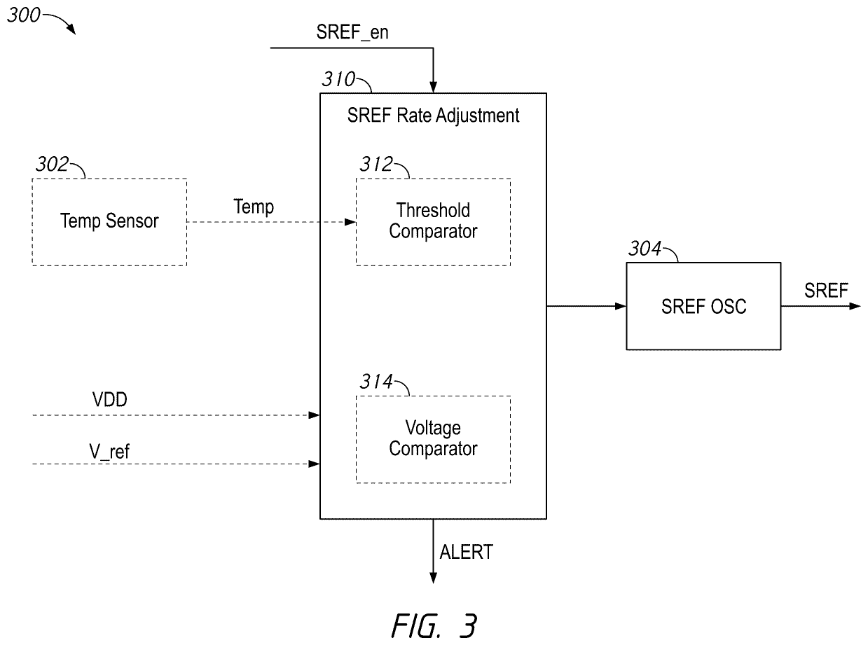

FIG. 3 is a block diagram of self-refresh logic according to some embodiments of the present disclosure. The self-refresh rate logic 300 may, in some embodiments, be included in a memory device such as 100 of FIG. 1, for example in refresh logic circuits such as 200 of FIG. 2. The self-refresh rate logic 300 includes a self-refresh rate adjustment circuit 310 (e.g., 142 of FIGS. 1 and/or 232 of FIG. 2) and a self-refresh oscillator circuit 304 (e.g., 140 of FIGS. 1 and/or 230 of FIG. 2). The self-refresh rate adjustment circuit 310 sets the rate at which the self-refresh oscillator circuit 304 provides the signal SREF during a self-refresh mode of the memory.

The self-refresh oscillator circuit 304 provides the signal SREF with periodic timing. For example, the signal SREF may be a binary signal where a pulse indicates an activation of SREF, and the rising edge of each pulse is separated from the rising edge of a next pulse by the periodic timing. The self-refresh rate adjustment circuit 310 provides one or more signals to control the periodic timing. The self-refresh rate adjustment circuit 310 may update the timing based on one or more conditions of the memory. Two example conditions, temperature and voltage are described with respect to FIG. 3. Either temperature or voltage may be used alone, or the two may both be used by the self-refresh rate adjustment circuit.

A temperature sensor 302 (e.g., 130 of FIG. 1) measures a temperature of the memory. For example, the temperature sensor 302 may be positioned close to a memory array and measure a temperature of the array. The temperature sensor 302 provides a signal TEMP which represents the measured temperature. In some embodiments, the temperature sensor may update the value of TEMP periodically at discrete time points. When the value of TEMP is updated, the self-refresh rate adjustment circuit 310 may check the value of TEMP to determine if the period of the self-refresh oscillator 304 should be changed. The self-refresh rate adjustment circuit 310 may reduce the self-refresh rate if the temperature rises above a safety threshold. In some embodiments, the self-refresh rate adjustment circuit 310 may generally increase the self-refresh rate with increasing temperature up until the safety threshold, at which point the rate may be decreased.

In an example implementation, the self-refresh rate adjustment circuit includes a threshold comparator 312 which compares the temperature signal TEMP to one or more thresholds. For example, the temperature signal TEMP is compared to a safety threshold and decrease the rate of the self-refresh oscillator 304 once the temperature signal TEMP crosses the safety threshold. In some embodiments, the threshold comparator may also compare the temperature signal TEMP to a hot threshold which is less than the safety threshold. When the temp signal TEMP crosses the hot threshold, the self-refresh rate adjustment circuit increases the self-refresh rate, and then decreases it if the temperature signal TEMP crosses the safety threshold. In some embodiments, the self-refresh rate adjustment circuit 310 may keep the self-refresh rate at a reduced level until the temperature signal TEMP falls below the hot threshold.

In an example implementation, the self-refresh rate adjustment circuit 310 may include voltage comparator 314 that receives a system voltage such as VDD and a reference voltage V_ref. The reference voltage may be VDDQ in some example embodiments. The system voltage is a voltage used to power refresh operations. Accordingly, if too many refresh operations are occurring, the level of the system voltage may decrease since more power may be drawn than can be supplied. The reference voltage V_ref may not be used as part of refresh operations, and may generally be expected to remain stable even if many refresh operations are occurring. If the system voltage drops below the reference voltage, the voltage comparator 314 signals the self-refresh oscillator circuit 304 to reduce the rate of self-refresh operations.

In some embodiments, if the self-refresh rate adjustment circuit reduces the self-refresh rate, either due to increased temperature or decreased voltage, then the self-refresh rate adjustment circuit may provide an alert signal ALERT or other signal to the controller. For example, the self-refresh rate adjustment circuit may reduce a self-refresh rate below a minimum rate of refresh operations needed to maintain the integrity of the data and may signal the controller that the information in the memory has been compromised. However, reducing the self-refresh rate in this manner may protect the memory from damage.

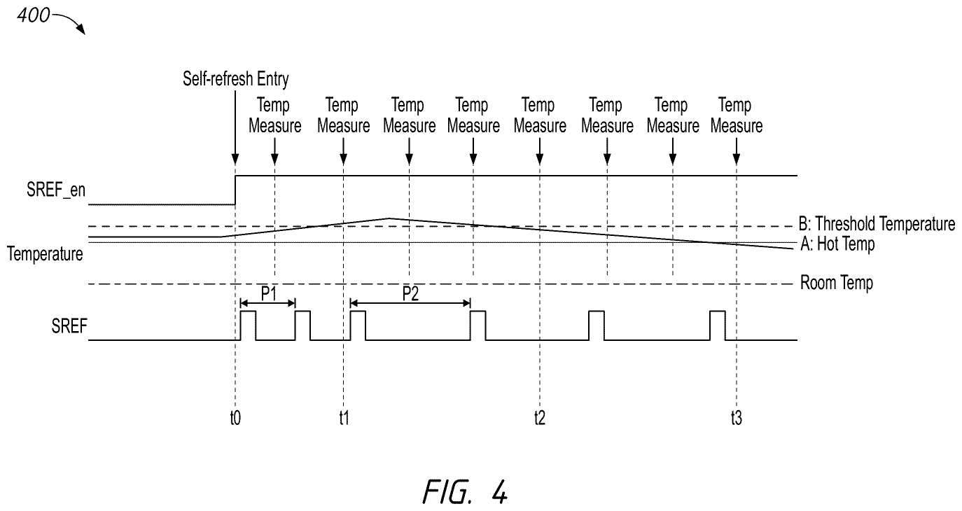

FIG. 4 is timing diagram of adjusting self-refresh operations based on temperature according to some embodiments of the present disclosure. The timing diagram 400 may, in some embodiments, represent the operations of a memory device or a portion thereof. For example, the timing diagram 400 may represent the operation of the memory device 100 of FIG. 1, the refresh logic 200 of FIG. 2, the self-refresh rate logic 300 of FIG. 3, or combinations thereof.

The timing diagram 400 shows three traces which share a common horizontal axis. The horizontal axis represents time. The top trace shows a self-refresh enable signal SREF_en which is at a logical low when it is inactive and at a logical high and when it is active. The middle trace shows a temperature of the memory, for example as measured by a temperature sensor (e.g., 130 of FIGS. 1 and/or 302 of FIG. 3). Arrows pointing down are shown along the top of the timing chart 400 to represent the time points at which the value of the temperature signal TEMP is updated based on the measured temperature. Also shown are two example thresholds, for example as used by a threshold comparator such as 312 of FIG. 3. Shown are a lower threshold “A” which represents a hot temperature threshold and a threshold “B” which represents a safety threshold. The bottom trace shows pulses of a self-refresh signal SREF generated by a self-refresh oscillator circuit (e.g., 140 of FIG. 1, 230 of FIG. 2, and/or 304 of FIG. 3).

At an initial time t0, the self-refresh enable signal SREF_en becomes active, and the memory enters a self-refresh mode. For example, a controller may send a self refresh entry command, which causes the self-refresh enable signal to become active until a self-refresh exit command is received. For example, the controller may also monitor the temperature of the memory, and may send the self-refresh entry command responsive to the temperature rising above A, the hot temperature threshold.

When the self-refresh enable signal SREF_en becomes active, the self-refresh oscillator circuit begins periodically providing pulses of the self-refresh signal SREF. Since the temperature is above the threshold A, the self-refresh signal is provided with a first period P1. FIG. 4 shows an example situation where the temperature continues to increase after the time t0. At a time t1, the temperature is measured again and is above B, the safety threshold. Responsive to this, a self-refresh rate adjustment circuit (e.g., 142 of FIG. 1, 232 of FIG. 2, and/or 310 of FIG. 3) reduces the rate at which the self-refresh signal SREF is provided. For example, after the time t1, the period of SREF pulses is P2, which is longer than the period P1.

Since the period of self-refresh operations increases at t1, the temperature will eventually begin to decrease. At a time t2, the temperature has decreased below the safety threshold B. However, the self-refresh period continues to be P2. At a time t3 the temperature has fallen below the hot threshold A. In some embodiments, after the time t3, the self-refresh rate may be increased again.

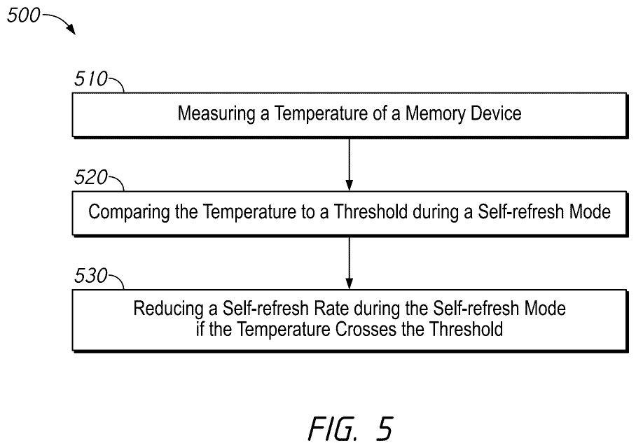

FIG. 5 is a flow chart of a method of adjusting a self-refresh rate based on temperature according to some embodiments of the present disclosure. The method 500 may, in some embodiments, be performed by one or more of the apparatuses or systems described herein. For example, the method 500 may be performed by a memory device such as 100 of FIG. 1, and/or a portion thereof such as the refresh logic 200 of FIG. 2, and/or the self-refresh logic 300 of FIG. 3.

The method 500 may generally begin with box 510, which describes measuring a temperature of a memory device. The method 500 may include measuring the temperature with a temperature sensor (e.g., 130 of FIGS. 1 and/or 302 of FIG. 3). In some embodiments, the method 500 may include periodically updating a temperature signal (e.g., TEMP) based on the measured temperature.

Box 510 may generally be followed by box 520, which describes comparing the temperature to a threshold during a self-refresh mode. The method 500 may include determining if the temperature has risen above the threshold. The threshold may be a safety threshold of the memory device. For example, the method 500 may include comparing a temperature signal (e.g., TEMP) to the threshold with a threshold comparator (e.g., 312 of FIG. 3). The method 500 may include comparing the temperature signal to the threshold when the temperature signal is updated.

Box 520 may be followed by box 530, which describes reducing the self-refresh rate during the self-refresh mode if the temperature crosses the threshold. For example, the method 500 may include reducing the self-refresh rate if the temperature is greater than the threshold. For example, the method 500 may include adjusting a rate of pulses of a self-refresh signal. For example, the method 500 may include periodically producing pulses of a self-refresh signal with a self-refresh oscillator (e.g., 140 of FIG. 1, 230 of FIG. 2, and/or 304 of FIG. 3) and changing the period of the pulses from a first period to a second, longer period responsive to the temperature crossing the threshold. The method may include performing one or more refresh operations responsive to each pulse of the self-refresh signal. In some embodiments, the method 500 may include performing one or more normal refresh operations responsive to the self-refresh signal.

The method 500 may include entering the memory into a self-refresh mode, for example responsive to a self-refresh entry command. The method 500 may include receiving the self-refresh entry command responsive to the temperature crossing a second threshold which is lower than the threshold. For example the second threshold may represent a ‘hot temperature’ threshold of the memory. In some embodiments, the method 500 may include keeping the reduced self-refresh rate until the temperature falls below the second threshold. In some embodiments, the method 500 may include reducing the self-refresh rate below a rate required to maintain data integrity on the device. In some embodiments, the method 500 may include sending an alert signal, for example to a controller, responsive to reducing the self-refresh rate.

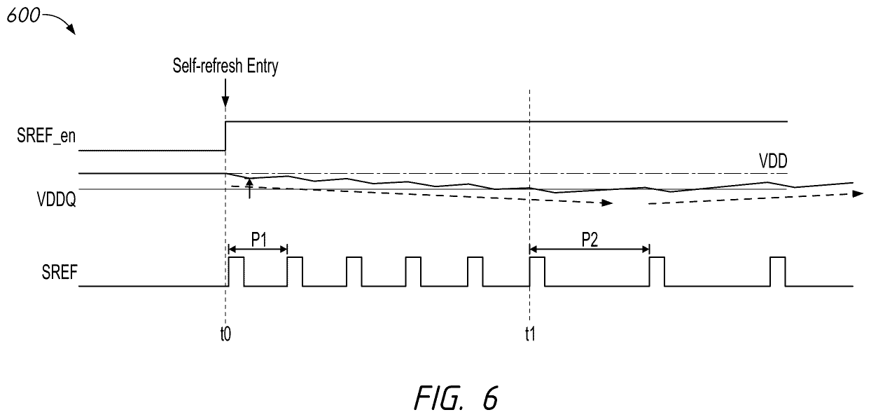

FIG. 6 is a timing diagram of adjusting self-refresh operations based on voltage according to some embodiments of the present disclosure. The timing diagram 600 may, in some embodiments represent the operations of a memory device or a portion thereof. For example, the timing diagram 600 may represent the operation of the memory device 100 of FIG. 1, the refresh logic 200 of FIG. 2, the self-refresh rate logic 300 of FIG. 3, or combinations thereof. The timing diagram 600 may be generally similar to the timing diagram 400 of FIG. 4, except the timing diagram 600 shows rate adjustment based on voltage.

The timing diagram 600 shows three traces which share a common horizontal axis. The horizontal axis represents time. The top trace shows a self-refresh enable signal SREF_en which is at a logical low when it is inactive and at a logical high and when it is active. The middle trace shows a system voltage, such as VDD. Also shown is a reference voltage level shown as a horizontal line, in this case the voltage VDDQ is used as the reference voltage. The bottom trace shows pulses of a self-refresh signal SREF generated by a self-refresh oscillator circuit (e.g., 140 of FIG. 1, 230 of FIG. 2, and/or 304 of FIG. 3).

At an initial time t0, the device enters a self-refresh mode. For example, the controller may send a self-refresh entry command. Responsive to that, a self-refresh enable signal SREF_en of the memory rises to an active level. Responsive to entering the self-refresh mode, the memory begins providing pulses of the self-refresh signal SREF. Starting at the time to, the self-refresh signal is provided at a first rate, with a period of P1. Responsive to a pulse of the self-refresh signal SREF, one or more refresh operations are performed. In some embodiments, multiple word lines may be refreshed at once. Starting at the time t0, there is a dip in the voltage VDD, for example because multiple word lines are activated and refreshed at one time. The level of VDD slowly increases again over time. However, in the example of FIG. 6, refresh operations are happening often enough that there is a net decrease in VDD over time.

At a time t1, the voltage VDD dips below the reference voltage VDDQ. This causes the self-refresh rate adjustment circuit to decrease the rate of self-refresh operations. For example, the period between the self-refresh signal is increased to P2, which is longer than P1. This allows the voltage VDD to recover back to a nominal level. In some embodiments, the increased period P2 may be long enough that it may allow for loss of information in the memory array. However, the drop in VDD during operations may have caused damage to the device. In some embodiments, the device may send an alert or other signal to a controller when it reduces the refresh rate at t1.

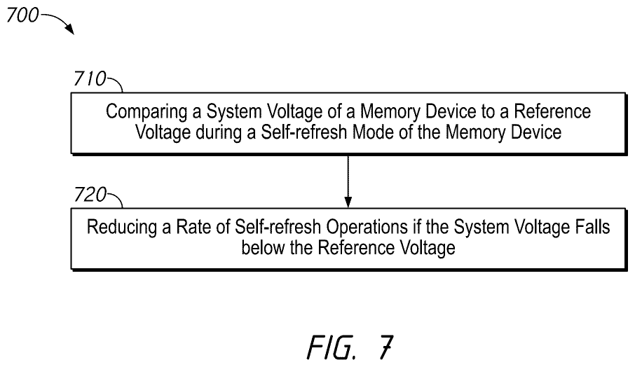

FIG. 7 is a flow chart of a method of adjusting a self-refresh rate based on voltage according to some embodiments of the present disclosure. The method 700 may, in some embodiments, be performed by one or more of the apparatuses or systems described herein. For example, the method 500 may be performed by a memory device such as 100 of FIG. 1, and/or a portion thereof such as the refresh logic 200 of FIG. 2, and/or the self-refresh logic 300 of FIG. 3.

The method 700 may generally begin with box 710, which describes comparing a system voltage of a memory device to a reference voltage during a self-refresh mode of the memory device. For example, the method 700 may include comparing the system voltage to the reference voltage with a voltage comparator circuit (e.g., 314 of FIG. 3) when a self-refresh enable signal is active. In some embodiments, the method 700 may include receiving the system voltage at a first voltage terminal and receiving the reference voltage at a second voltage terminal. The method 700 may include using a voltage as the system voltage which is used during refresh operations and using a voltage as the reference voltage which is not used during refresh operations.

In an example implementation, the system voltage may be VDD and the reference voltage may be VDDQ. The voltage VDD, or one or more voltages derived therefrom, is used to power the array, and thus is used to activate word lines during refresh operations. The voltage VDDQ is used to power data terminals, which are not used during refresh operations.

Box 710 is generally followed by box 720, which describes reducing a rate of self-refresh operations if the system voltage falls below the reference voltage. For example, if the voltage comparator determines that the system voltage is less than the reference voltage, the method 700 may include increasing a period of a self-refresh signal. The method 700 may include periodically generating pulses of a self-refresh signal while in the self-refresh mode, and performing one or more refresh operations responsive to each pulse of the self-refresh signal. In some embodiments, the method 700 may include refreshing multiple word lines as part of the refresh operation responsive to the self-refresh signal.

In some embodiments, the method 700 may include reducing the self-refresh rate below a rate required to maintain data integrity on the device. In some embodiments, the method 700 may include sending an alert signal, for example to a controller, responsive to reducing the self-refresh rate. In some embodiments, the method 700 may include maintaining the self-refresh rate at the reduced rate until the system voltage rises above the reference voltage.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a refresh control circuit configured to perform a refresh operation responsive to a pulse of a self-refresh signal;
a self-refresh oscillator configured to periodically provide pulses of the self-refresh signal at a rate;
a self-refresh rate adjustment circuit configured to compare a system voltage to a reference voltage and reduce the rate at which the self-refresh oscillator provides the pulses of the self-refresh signal based on the comparison.

2. The apparatus of claim 1, wherein the self-refresh rate adjustment circuit is configured to reduce the rate when the system voltage is less than reference voltage.

3. The apparatus of claim 2, wherein the self-refresh rate adjustment circuit is configured to change a period of the self-refresh oscillator from a first period to a second period which is longer than the first period, responsive to the system voltage being less than the reference voltage.

4. The apparatus of claim 1, further comprising:
a first voltage terminal configured to receive system voltage; and
a second voltage terminal configures to receive reference voltage.

5. The apparatus of claim 4, wherein the system voltage is VDD and the reference voltage is VDDQ.

6. The apparatus of claim 1, wherein the refresh control circuit is configured to refresh multiple word lines responsive to each pulse of the self-refresh signal.

7. The apparatus of claim 1, wherein the self-refresh rate adjustment circuit is configured to compare the system voltage to the reference voltage during a self-refresh mode.

8. The apparatus of claim 1, wherein the self-refresh rate adjustment circuit is configured to provide an alert signal responsive to reducing the rate of the self-refresh signal.

9. A method comprising:
comparing a system voltage of a memory device to a reference voltage during a self-refresh mode of the memory device; and
reducing a rate of self-refresh operations if the system voltage falls below the reference voltage.

10. The method of claim 9, further comprising:
periodically providing a self-refresh signal during a self-refresh mode; and
performing a self-refresh operation by refreshing one or more word lines responsive to the self-refresh signal.

11. The method of claim 10, further comprising reducing the rate by changing the period of the self-refresh signal from a first period to a second period.

12. The method of claim 10, further comprising refreshing multiple word lines at a same time responsive to the self-refresh signal.

13. The method of claim 9, wherein the system voltage is VDD and the reference voltage is VDDQ.

14. The method of claim 9, further comprising comparing the system voltage to the reference voltage while a self-refresh enable signal is active.

15. The method of claim 9, further comprising sending an alert signal responsive to reducing the rate of the self-refresh operations.

16. An apparatus comprising:
a refresh control circuit configured to periodically perform self-refresh operations in a self-refresh mode; and
a self-refresh rate adjustment circuit configured to change a rate of the self-refresh operations if a system voltage falls below a reference voltage.

17. The apparatus of claim 16, further comprising:
a self-refresh oscillator configured to provide pulses of a self-refresh signal,
wherein the refresh control circuit configured to perform refresh operation responsive to the self-refresh signal, and
wherein the self-refresh rate adjustment circuit is configured to change the rate at which the self-refresh oscillator provides the pulses of the self-refresh signal.

18. The apparatus of claim 16, further comprising:
a memory array; and
an input/output circuit, wherein the system voltage is used by the memory array and the reference voltage is used by the input/output circuit but not the memory array.

19. The apparatus of claim 18, wherein the system voltage is VDD and the reference voltage is VDDQ.

20. The apparatus of claim 16, wherein the self-refresh rate adjustment circuit is configured to provide an alert signal responsive to changing the rate of the pulses of the self-refresh signal.
